(19) United States
(12) Patent Application Publication
(10) Pub. No.: US 2007/0012240 A1
(43) Pub. Date: Jan. 18, 2007

(54) Light emitting diode with at least two light emitting zones and method for manufacture

(76) Inventors: Chin Hian Sia, Singapore (SG); Soo Kiang Ho, Singapore (SG); Thiam Siew Gary Tay, Singapore (SG); Leonard Ian Kheng Tan, Singapore (SG); Soo Hiong Lee, Singapore (SG); Soon Aun Andy Poh, Singapore (SG)

Correspondence Address: AVAGO TECHNOLOGIES, LTD., P.O. BOX 1920, DENVER, CO, 80201-1920, US

(21) Appl. No.: 11/180,939

(22) Filed: Jul. 13, 2005

(51) Int. Cl. C30B 23/00; C30B 25/00; C30B 28/12; C30B 28/14

(52) U.S. Cl. 117/86

(57) ABSTRACT

A light emitting diode includes a first light emitting zone and a second light emitting zone. A defect propagation confinement mechanism is disposed in relation to the first light emitting zone and the second light emitting zone. The defect propagation confinement mechanism prevents defects in either the first light emitting zone or the second light emitting zone from propagating to the other light emitting zone.

### BACKGROUND OF THE INVENTION

Light emitting diodes (LEDs) have many useful commercial applications. Because they are monochromatic, LED lights have great power advantages over white lights especially in applications in which a specific color light is needed. Unlike the white lights, the LED does not need a color filter that absorbs most of the emitted white light. Since LED lights are inherently colored and are available in a wide range of colors, LEDs have become of choice in many lighting applications.

For example, one of the most recently introduced colors is an emerald green or bluish green LED (about 500 nm) that meets the requirements for traffic signals and navigation lights. Also, LEDs find many applications in other electronic applications.

However, as electronic applications become more complex and demanding, there remains a need for slowing or stopping the degradation of the light emitting diodes (LEDs). The degradation of LEDs can result from defects in the light emitting diode. These defects include crystal defects, defects due to micro-cracks, and defects due to scratches in the diode. Consequently, the opto-electronic device (e.g., LED) can cease to perform as designed and can result in either failure or a reduction in the quality of the device.

Attempts have been made by the opto-electronic industry to reduce these failures by attacking the root cause of theses problems. For example, crystal defects may be reduced by manufacturing purer wafer ingots. Similarly, scratches and defects may be reduced by introducing more expensive processing equipment in the wafer processing and by promoting more vigorous quality testing and quality inspection (e.g., more thorough visual inspection).

Unfortunately, although the above-mentioned methods reduced the number of failures, failures that occur in the field after leaving the manufacturer cannot be prevented or eliminated. For example, a latent defect can grow and propagate due to electrical stresses on the device during usage of the LED in the field. In other words, stresses encountered in the field can promote defect propagation in the LED. First, the defective region does not produce light (e.g., becomes a dark region). Second, and perhaps more detrimental, the defective region provides a current leakage path that draws away useful current from regions that produce light (i.e., the undamaged regions). The net result is that the light generated by the LED is significantly reduced for the same amount of supply current.

Based on the foregoing, there remains a need for a light emitting diode with at least two light emitting areas and method for manufacturing the light emitting diode that overcomes the disadvantages set forth previously.

### SUMMARY OF THE INVENTION

According to one embodiment of the invention, a light emitting diode with at least two light emitting zones and method for manufacture is described. A light emitting diode is formed that includes a first light emitting zone and a second light emitting zone. A defect propagation confinement mechanism is disposed in relation to the first light emitting zone and the second light emitting zone. The defect propagation confinement mechanism prevents defects in either the first light emitting zone or the second light emitting zone from propagating to the other light emitting zone.

### BRIEF DESCRIPTION OF THE DRAWINGS

The present invention is illustrated by way of example, and not by way of limitation, in the figures of the accompanying drawings and in which like reference numerals refer to similar elements.

FIG. 1 illustrates a block diagram of an opto-electronic device with a first light emitting zone and a second light emitting zone.

FIG. 2 illustrates a top view of a light emitting diode with two light emitting areas according to one embodiment of the invention.

FIG. 3 illustrates a top view of a light emitting diode with four light emitting areas according to a second embodiment of the invention.

FIG. 4 illustrates a section view of the light emitting diode of FIGS. 2 and 3 through lines 4-4 according to one embodiment of the invention.

FIG. 5 illustrates a top view of a light emitting diode with two light emitting areas according to a third embodiment of the invention.

FIG. 6 illustrates a section view of a light emitting diode of FIG. 5 through lines 6-6 according to one embodiment of the invention.

FIG. 7 is a flowchart illustrating a method for manufacturing a light emitting diode with at least two light emitting areas according to a one embodiment of the invention.

### DETAILED DESCRIPTION

Light emitting diode (LED) with at least two light emitting zones and a method for manufacturing the LED are described. In the following description, for the purposes of explanation, numerous specific details are set forth in order to provide a thorough understanding of the present invention. It will be apparent, however, to one skilled in the art that the present invention may be practiced without these specific details. In other instances, well-known structures and devices are shown in block diagram form in order to avoid unnecessarily obscuring the present invention.

Opto-Electronic Device 100

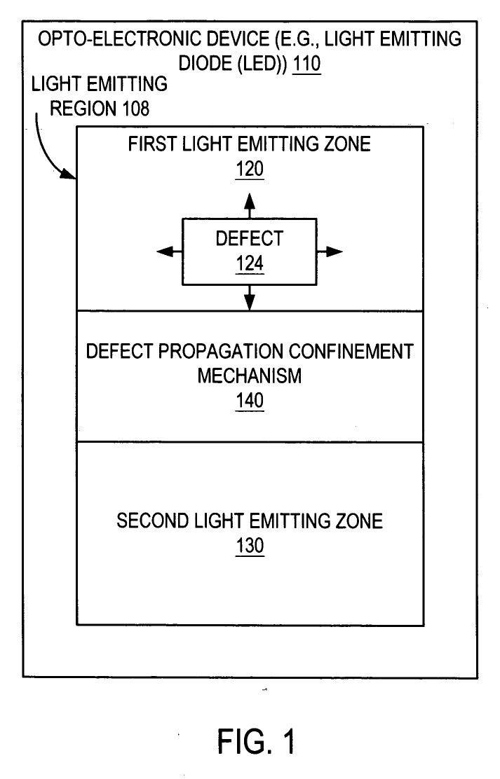

FIG. 1 illustrates a block diagram of an opto-electronic device 110 with a first light emitting zone 120 and a second light emitting zone 130. The opto-electronic device 110 can be, for example, a light emitting diode (LED) that includes semiconductor material doped or impregnated with impurities to create a structure that is commonly referred to as a p-n junction. Charge-carriers (e.g., electrons and holes) flow into the junction from electrodes with different voltages. When an electron meets a hole, the electron falls into a lower energy level and releases energy in the form of a photon, thereby emitting light.

For example, when the voltage across the p-n junction has a correct polarity, a significant current flows across the p-n junction, and the LED is said to be “forward-biased.” In this case, the voltage across the LED is fixed and is proportional to the energy of the emitted photons. However, when the voltage has an incorrect polarity, the LED is said to be “reverse biased,” and very little current flows across the p-n junction, and no light is emitted.

The wavelength of the light emitted, and therefore its color, depends on the bandgap energy of the materials forming the p-n junction. For example, the materials used for LEDs have bandgap energies corresponding to near-infrared, visible or near-ultraviolet light.

The light emitting diode 110 includes a light emitting region 108 that emits light when a voltage potential is applied to the LED 110. In one example, the light emitting region 108 includes a p-n junction that generates light when a voltage is applied across the p-n junction. The light emitting diode (LED) 110 is a semiconductor diode that converts electric energy into electromagnetic radiation at predetermined frequencies (e.g., visible and near infrared frequencies) when its p-n junction is forward biased.

The light emitting region 108 can include a defect, such as defect 124 in the first light emitting zone 120. Left to itself, the defect 124 can grow, spread, or propagate in one or more directions. For example, the defect 124 can propagate along a first direction (e.g., along an x-axis), a second direction (e.g., along a y-axis), a third direction (e.g., along a z-axis), or a combination thereof.

The opto-electronic device 110 includes a defect propagation confinement mechanism (DPCM) 140. According to one embodiment of the invention, the opto-electronic device 110 utilizes the defect propagation confinement mechanism (DPCM) 140 to reduce the risk of failure of the LED when a specific section of the light emitting area 108 is damaged. The damage can be due, for example, to crystal defects, defects due to scratches, or defects due to micro cracks.

The defect propagation confinement mechanism (DPCM) 140 separates the light emitting region 108 into at least two light emitting zones (e.g., a first light emitting zone 120 and second light emitting zone 130). Furthermore, the DPCM 140 confines the propagation of the defect 124 to a particular zone in which the defect is located and prevents the propagation or growth of the defect to another zone of the light emitting region 108. By isolating the defect and disallowing the defect to spread to other zones in the light emitting region 108, the DPCM 140 effectively controls the size or extent to which the defect can grow, thereby reducing the adverse effects of the defect on light output and proper operation of the light emitting diode.

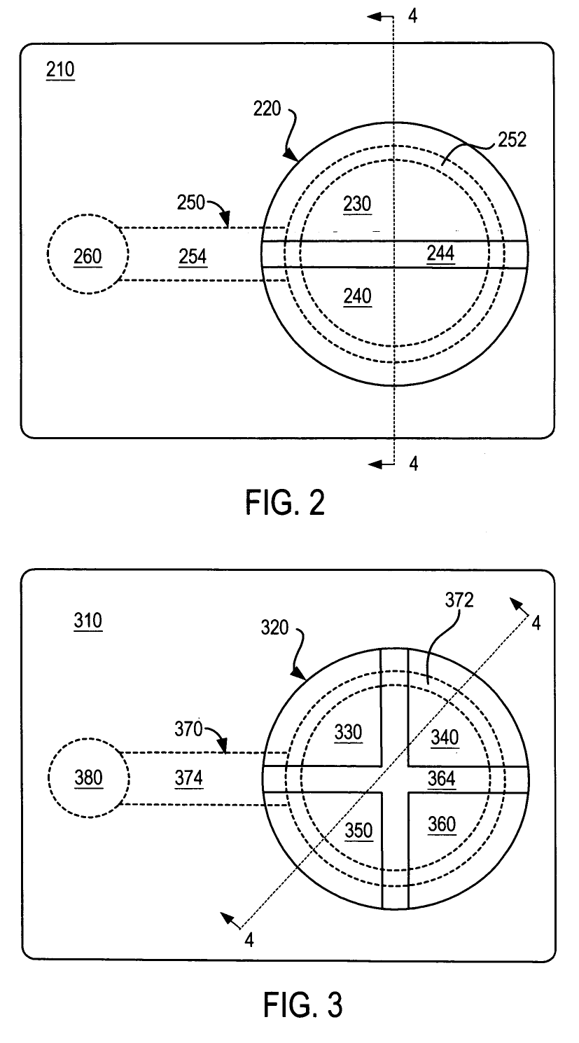

In one embodiment, the DPCM 140 forms at least a portion of the boundary of the first light emitting zone 120 and a portion of the boundary of the second light emitting zone 130. In one embodiment, the DPCM 140 confines or stops the growth or propagation of a defect in at least one direction. In another embodiment, the DPCM 140 confines or stops the growth or propagation of a defect in a first direction, in a second direction, or a combination thereof. Variations in the size, shape and number of light emitting zones are described in greater detail hereinafter with reference to FIGS. 2-6.

### First Embodiment with Two Light Emitting Areas

FIG. 2 illustrates a top view of a light emitting diode 210 with two light emitting areas 230, 240 according to one embodiment of the invention. The light emitting diode 210 includes an active area (e.g., a light emitting region) 220. The light emitting region 220 includes a first light emitting zone or area 230 and a second light emitting zone or area 240 that are separated by a defect propagation confinement mechanism 244.

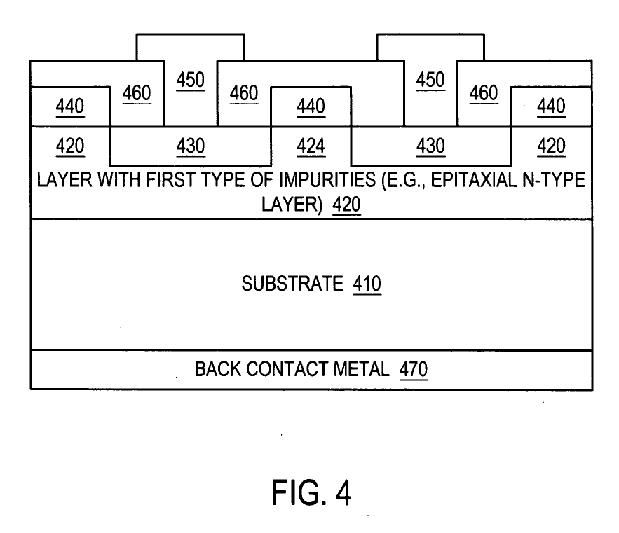

The light emitting diode 210 includes a conductive layer 250 (e.g., metallization) 250 and an interconnect pad 260 (e.g., a pad for connection to external contacts). The conductive layer 250 includes a ring portion 252 that electrically connects to the light emitting zones 230, 240 and a bridge portion 254 that electrically connects the ring portion 252 to the pad 260. A sectional view of the light emitting diode 210 through line 4-4 is described with reference to FIG. 4.

### Second Embodiment with Four Light Emitting Areas

FIG. 3 illustrates a top view of a light emitting diode 310 with four light emitting areas 330, 340, 350, 360 according to a second embodiment of the invention.

The light emitting diode 310 includes an active area (e.g., a light emitting region) 320. The active area 320 includes a first light emitting area 330, a second light emitting area 340, a third light emitting area 350, and a fourth light emitting area 360. Each of the light emitting areas is separated from each other by a defect propagation confinement mechanism 364.

The light emitting diode 310 includes a conductive layer (e.g., metallization) 370 and an interconnect pad 380 (e.g., a pad for connection to external contacts). The conductive layer 370 includes a ring portion 372 that electrically connects to the light emitting zones 330, 340, 350, 360 and a bridge portion 374 that electrically connects the ring portion 372 to the pad 380. A sectional view of the light emitting diode 310 through line 4-4 is described with reference to FIG. 4.

Referring to FIG. 4, the LED includes a substrate 410. A metal layer 470 (e.g., a back contact metal) is formed on one side of the substrate 410. A layer 420 with a first type of impurity is formed on the other side of the substrate 502. In one embodiment, the layer 420 is an epitaxial n-type layer. Layer 440 is a first passivation layer in which windows are opened for junction formation. For example, the windows in the first passivation layer 440 are utilized to implant or dope a region in layer 420 with p-type impurities to form a p-n junction. For example, regions 430 can be regions where p-type impurities have been implanted. Region 424 can be the defect propagation confinement mechanism (DPCM) 140 according to the invention.

Layer 460 is a second passivation layer in which windows are opened for forming a contact (e.g., a top contact metal layer) with the LED. For example, the conductive layer 450 (e.g., 250, 370 in FIGS. 2 and 3) electrically couples the light emitting zones to an external contact through metallization and a pad.

### Third Embodiment Where Each Light Emitting Area has a Separate Interconnect Pad

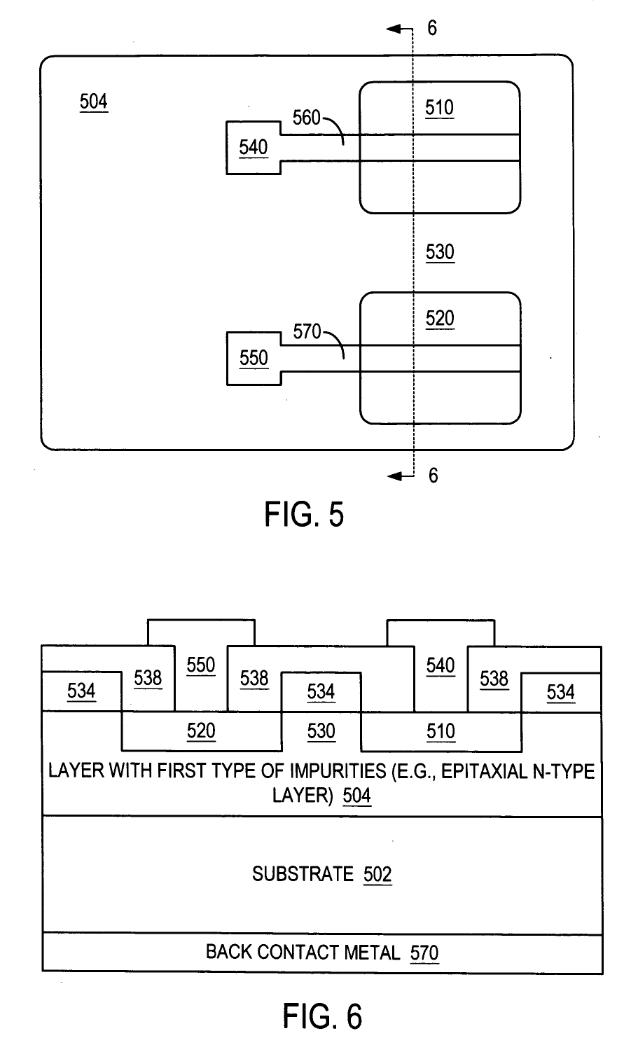

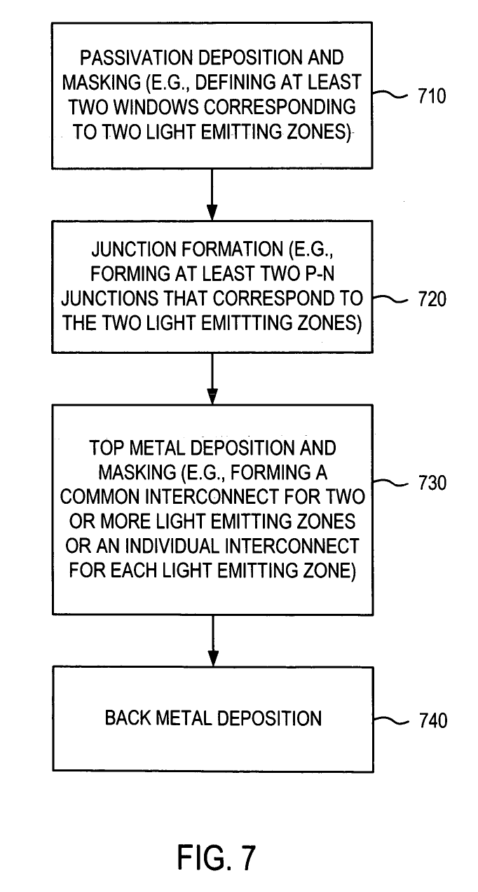

FIG. 5 illustrates a top view of a light emitting diode 504 with two light emitting areas 510, 520 according to a third embodiment of the invention. The first light emitting area 510 has a corresponding interconnect pad 540. Similarly, the second light emitting area 520 has a corresponding interconnect pad 550. It is noted in this embodiment, that each light emitting area has a separate and corresponding interconnect pad 540, 550. FIG. 6 illustrates a section view of a light emitting diode 504 of FIG. 5 through lines 6-6 according to one embodiment of the invention.

Referring to FIG. 6, the LED 504 includes a substrate 502. A metal layer 570 (e.g., a back contact metal) is formed on one side of the substrate 502. A layer 504 with a first type of impurity is formed on the other side of the substrate 502. In one embodiment, the layer 504 is an epitaxial n-type layer. Layer 534 is a first passivation layer in which windows are opened for junction formation. For example, the windows in the first passivation layer 534 are utilized to implant or dope a region in layer 504 with p-type impurities to form a p-n junction. For example, regions 510, 520 can be regions where p-type impurities have been implanted. Region 530 can be the defect propagation confinement mechanism (DPCM) 140 according to the invention.

Layer 538 is a second passivation layer in which windows are opened for forming a contact (e.g., a top contact metal layer) with the LED. For example, the conductive layer 540 (e.g., 560, 570 in FIG. 5) electrically couples the light emitting zones to an external contact through metallization and a pad.

Number of Light Emitting Areas

It is noted that number of the light emitting areas (LEAs) per unit die (e.g., per LED die) can be varied, adjusted, or modified to suit the requirements of a particular application. It is further noted that as the design of the light emitting diode increases the number of light emitting areas or zones according to one embodiment of the invention, defects in the light emitting diode are isolated in a quicker fashion. For example, as the LED design utilizes or employs more light emitting areas or zones in a single die, the time in which a defect in one of the zones is limited or isolated decrease since there is less distance for a defect to grow or propagate before encountering a defect propagation confinement mechanism provided that the size of all the total light emitting areas remains constant.

Shape of the Light Emitting Areas

It is noted that shape or geometry of the light emitting areas (LEAs) can be varied, adjusted, or modified to suit the requirements of a particular application. It is further noted that the light emitting areas can all have a uniform or similar shape, all have different shapes, or two or more light emitting areas can have the same or similar shape and the remaining light emitting areas can have a different shape. It is noted that the size of the different light emitting zones may be different or substantially the same.

### Process to Manufacture the Light Emitting Diode with at Least Two light Emitting Zones

The processing to manufacture the LED with at least two light emitting zones includes four main categories: 1) passivation deposition and masking; 2) junction formation; 3) metal deposition and masking; and 4) back metal deposition. Prior to processing, a layer (e.g., 420, 504) is manufactured by an epitaxy process by which a thin layer of single-crystal material is deposited on a single-crystal substrate (e.g., 410, 502). For example, epitaxial growth can occur in such way that the crystallographic structure of the substrate is reproduced in the growing material.

In step 710, passivation deposition and masking are performed. For example, at least two windows corresponding to two light emitting zones are defined. In step 720, junction formation is performed. For example, at least two p-n junctions that correspond to the two light emitting zones are formed.

In step 730, top metal deposition and masking is performed. For example, a common interconnect is formed for two or more light emitting zones or an individual interconnect is formed for each light emitting zone). In step 740, back metal deposition is performed.

Applications for LED with Multiple LEAs

The LED according to the invention may be used in many different applications that include, but are not limited to, information indicators in various types of embedded systems, message displays (e.g. public information signs at airports and railway stations, among other places), status indicators (e.g. as on/off lights on professional instruments and consumers audio/video equipment), in infrared LEDs in remote controls (for TVs, VCRs, etc), in traffic signals, as car indicator lights, in bicycle lighting, in calculator and measurement instrument displays, in illumination (e.g. flashlights), as backlights for LCD screens, as signaling/emergency beacons and strobes, in movement sensors applications (e.g., in mechanical and optical computer mice and trackballs) and in LED printers.

LEDs offer benefits in terms of maintenance and safety when compared to other light sources. The typical working lifetime of a device, including the bulb, is ten years, which is much longer than the lifetimes of most other light sources. Furthermore, LEDs fail by dimming over time, rather than the abrupt burn-out of incandescent bulbs. Also, LEDs give off less heat than incandescent light bulbs and are less fragile than fluorescent lamps. Since an individual device is smaller than a centimeter in length, LED-based light sources used for illumination and outdoor signals are built using clusters of tens of devices.

The defect propagation confinement mechanism according to one embodiment of the invention confines the growth of defects or the propagation thereof to a maximum of the light emitting area or zone in which the latent defect exists. For example, as the defect continues to grow due to stress, the defect is limited or confined to the light emitting area since the light emitting area or zone is isolated from other light emitting areas or zones by the defect propagation confinement mechanism according to one embodiment of the invention. In this manner, a light emitting diode with two or more light emitting zones or areas according to one embodiment of the invention provides a distributed risk management capability in a single LED. The risk of LED failure can be significantly reduced when a specific section of a light emitting area is damaged since the remaining light emitting areas, sections, or zones are isolated from the defect and protected from propagation of the defect into the remaining light emitting zones.

In the foregoing specification, the invention has been described with reference to specific embodiments thereof. It will, however, be evident that various modifications and changes may be made thereto without departing from the broader scope of the invention. The specification and drawings are, accordingly, to be regarded in an illustrative rather than a restrictive sense.

What is claimed is:

1. A method of manufacturing a light emitting diode with at least two light emitting zones comprising:
forming a first light emitting zone;
forming a second light emitting zone; and
forming a defect propagation confinement mechanism that is disposed in relation to the first light emitting zone and the second light emitting zone and that prevents a defect in one of the first light emitting zone and the second light emitting zone from propagating to the other light emitting zone.

2. The method of claim 1 wherein the first light emitting zone includes a surface; wherein the second light emitting zone includes a surface; wherein the defect propagation confinement mechanism is disposed between the surface of first light emitting zone and the surface of second light emitting zone and prevents defect propagation in at least a first direction.

3. The method of claim 1 wherein the defect propagation confinement mechanism includes one of a region that is doped with a first type of impurity and a region that is doped with a second type of impurity.

4. The method of claim 3 wherein the defect propagation confinement mechanism includes one of a region that is doped with n-type impurity and a region that is doped with p-type impurity.

5. The method of claim 1 wherein the defect propagation confinement mechanism is disposed between the first light emitting zone and the second light emitting zone and prevents defect propagation along at least a first direction.

6. A method of manufacturing a light emitting diode with at least two light emitting regions comprising:
providing a substrate;
depositing the substrate with a first type of impurity to form a first semiconductor region;
forming a first passivation layer on the first semiconductor layer;
forming at least two windows in the first passivation layer;
depositing a second type of impurity to form a second semiconductor region in the windows defined in the first passivation layer;
forming a second passivation layer;
forming at least two windows in the second passivation layer; and
depositing a conductive material in the windows defined in the second passivation layer.

7. A light emitting diode comprising:
a first light emitting zone; wherein the first light emitting zone generates a first light output in response to a first current and includes a defect;
a second light emitting zone that generates a second light output in response to a second current; and
a defect propagation confinement mechanism that prevents the defect in the first light emitting zone from propagating to the second light emitting zone and affecting the light generation of the second light emitting area.

8. The diode of claim 7 wherein the first light emitting zone includes a first region doped with a first type of impurity and a second region dope with a second type of impurity; wherein the first region and the second region form a first junction.

9. The diode of claim 8 wherein the first region is doped with a p-type impurities and the second region is doped with n-type impurities; wherein the first region and the second region form a first p-n junction.

10. The diode of claim 7 wherein the defect propagation confinement mechanism includes one of a region that is doped with a first type of impurity and a region that is doped with a second type of impurity.

11. The diode of claim 7 wherein the defect propagation confinement mechanism isolates the first light emitting zone from the second light emitting zone along at least a first direction.

12. The diode of claim 7 wherein the first light emitting zone includes a surface; wherein the second light emitting zone includes a surface; wherein the defect propagation confinement mechanism is disposed between the surface of the first light emitting zone and the surface of the second light emitting area.

13. The diode of claim 7 wherein the defect propagation confinement mechanism includes one of a region that is doped with n-type impurity and a region that is doped with p-type impurity.
